(19) United States
(12) Patent Application Publication
(10) Pub. No.: US 2019/0013449 A1
(43) Pub. Date: Jan. 10, 2019

(54) LIGHT-EMITTING DEVICE, ILLUMINATING APPARATUS, AND MOUNTING BOARD

(71) Applicant: PANASONIC INTELLECTUAL PROPERTY MANAGEMENT CO., LTD., Osaka (JP)

(72) Inventor: Toshifumi OGATA, Osaka (JP)

(73) Assignee: PANASONIC INTELLECTUAL PROPERTY MANAGEMENT CO., LTD., Osaka (JP)

(21) Appl. No.: 16/025,599

(22) Filed: Jul. 2, 2018

(30) Foreign Application Priority Data
Jul. 10, 2017 (JP) 2017-134425

(51) Int. Cl. H01L 33/54; H01L 25/075; H01L 33/62; F21V 23/02

(52) U.S. Cl. CPC H01L 33/54; H01L 25/0753; F21S 8/026; F21V 23/02; H01L 33/62

(57) ABSTRACT

A light-emitting device includes a substrate, a light-emitting element row disposed on the substrate, a first wire disposed on the substrate, a bonding wire electrically connecting the light-emitting element row and the first wire, a sealant that seals the light-emitting element row, and an enclosing component that is in a shape of a ring and surrounds the sealant. The first wire includes a first outer wire and a first inner wire that run in parallel along the ring, and a first connecting wire that is located between the first outer wire and the first inner wire and electrically connects the first outer wire and the first inner wire. The enclosing component covers a surface of the substrate exposed between the first outer wire and the first inner wire.

### CROSS REFERENCE TO RELATED APPLICATION

This application claims the benefit of priority of Japanese Patent Application Number 2017-134425 filed on Jul. 10, 2017, the entire content of which is hereby incorporated by reference.

### BACKGROUND

### 1. Technical Field

The present disclosure relates to a light-emitting device, an illuminating apparatus using the light-emitting device, and a mounting board.

### 2. Description of the Related Art

Light-emitting devices that emit white light by sealing a light-emitting element such as a light-emitting diode (LED) chip using a sealant containing phosphor are conventionally known. Japanese Unexamined Patent Application Publication No. 2012-015176 discloses a light-emitting device in which determination of whether or not a light-reflecting material is displaced can be performed accurately and instantly.

### SUMMARY

In the above-described light-emitting device, preventing detachment of a ring-shaped light-reflecting material (hereafter also referred to as an enclosing component) poses a challenge.

The present disclosure provides a light-emitting device, an illuminating apparatus, and a mounting board that are capable of preventing detachment of an enclosing component.

A display device according to an aspect of the present disclosure includes: a substrate; a light-emitting element row disposed on the substrate; a first wire disposed on the substrate; a first bonding wire electrically connecting the light-emitting element row and the first wire; a sealant that seals the light-emitting element row; and an enclosing component that is in a shape of a ring and surrounds the sealant, wherein the first wire includes: a first outer wire and a first inner wire that run in parallel along the ring, the first inner wire being located inward of the first outer wire; and a first connecting wire that is located between the first outer wire and the first inner wire, and electrically connects the first outer wire and the first inner wire, and the enclosing component covers a surface of the substrate exposed between the first outer wire and the first inner wire.

An illuminating apparatus according to an aspect of the present disclosure includes the above-described light-emitting device; and a lighting device that supplies, to the light-emitting device, power for causing the light-emitting device to emit light.

A mounting board according to an aspect of the present disclosure is a mounting board on which a light-emitting element row and an enclosing component that is in a shape of a ring and surrounds the light-emitting element row are to be disposed, and includes: a substrate; and a first wire disposed on the substrate, wherein the first wire includes: a first outer wire and a first inner wire that run in parallel along the ring, the first inner wire being located inward of the first outer wire; and a first connecting wire that is located between the first outer wire and the first inner wire, and electrically connects the first outer wire and the first inner wire.

A light-emitting device, an illuminating apparatus, and a mounting board according to an aspect of the present disclosure are capable of preventing detachment of an enclosing component.

### BRIEF DESCRIPTION OF DRAWINGS

The figures depict one or more implementations in accordance with the present teaching, by way of examples only, not by way of limitations. In the figures, like reference numerals refer to the same or similar elements.

FIG. 1 is an external perspective view of a light-emitting device according to Embodiment 1;

FIG. 2 is a plan view of the light-emitting device according to Embodiment 1;

FIG. 3 is a plan view illustrating the internal structure of the light-emitting device according to Embodiment 1;

FIG. 4 is a schematic cross-sectional view of the light-emitting device along line IV-IV in FIG. 2;

FIG. 5A is a first schematic cross-sectional view illustrating the structure of a light-emitting device in a comparative example;

FIG. 5B is a second schematic cross-sectional view illustrating the structure of a light-emitting device in a comparative example;

FIG. 6A is a first schematic cross-sectional view in which the periphery of a first wire of the light-emitting device according to Embodiment 1 is illustrated magnified;

FIG. 6B is a second schematic cross-sectional view in which the periphery of a first wire of the light-emitting device according to Embodiment 1 is illustrated magnified;

FIG. 6C is a third schematic cross-sectional view in which the periphery of a first wire of the light-emitting device according to Embodiment 1 is illustrated magnified;

FIG. 7 is a plan view illustrating alignment marks disposed on a substrate;

FIG. 8 is a schematic cross-sectional view of the light-emitting device in which the entirety of a bonding wire is sealed by a sealant;

FIG. 9 is a plan view of a first inner wire and a second inner wire which have inner sides that are step-shaped;

FIG. 10 is a cross-sectional view of an illuminating apparatus according to Embodiment 2; and

FIG. 11 is an external perspective view of the illuminating apparatus and peripheral components thereof according to Embodiment 2.

### DETAILED DESCRIPTION OF THE EMBODIMENTS

Hereinafter, exemplary embodiments will be described with reference to the drawings. It should be noted that each of the exemplary embodiments described below represents a generic or specific example. The numerical values, shapes, materials, structural components, the arrangement and connection of the structural components, etc. shown in the subsequent exemplary embodiments are mere examples, and are not intended to limit the scope of the present invention. Furthermore, among the structural components in the following embodiments, components not recited in any one of the independent claims which indicate the broadest concepts of the present invention are described as arbitrary structural components.

It should be noted that the respective figures are schematic diagrams and are not necessarily precise illustrations. Furthermore, in the respective figures, substantially identical components are assigned the same reference signs, and overlapping description may be omitted or simplified.

Furthermore, there are instances where coordinate axes are illustrated in the figures used to describe the subsequent exemplary embodiments. The Z-axis direction in the coordinate axes is for example the vertical direction, the positive side of the Z-axis is referred to as the top side (above/upward) and the negative side of Z-axis is referred to as the bottom side (below/downward). In other words, the Z-axis direction is a direction perpendicular to a substrate included in a light-emitting device. Furthermore, the X-axis direction and the Y-axis direction are mutually orthogonal directions in a plane (horizontal plane) perpendicular to the Z-axis direction. An X-Y plane is a plane parallel to a principal face of the substrate included in the light-emitting device. For example, in the subsequent exemplary embodiments, “plan view” means viewing from the Z-axis direction.

### Embodiment 1

[Configuration of Light-Emitting Device]

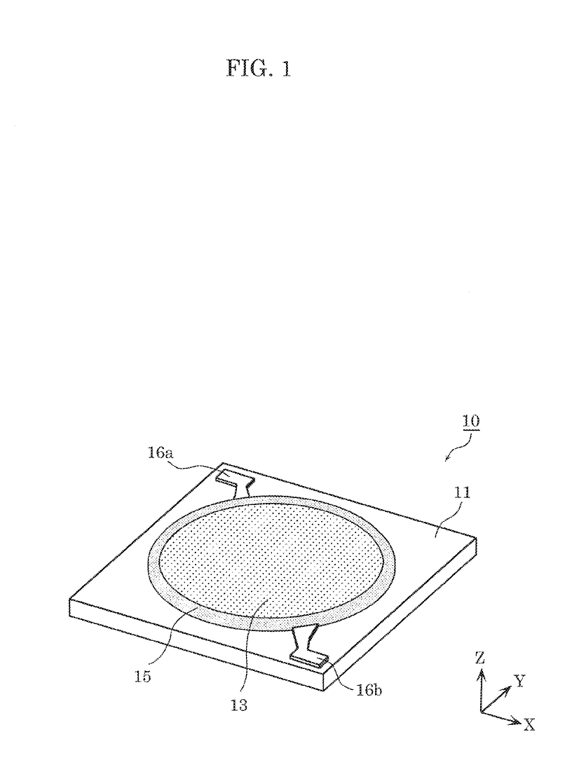

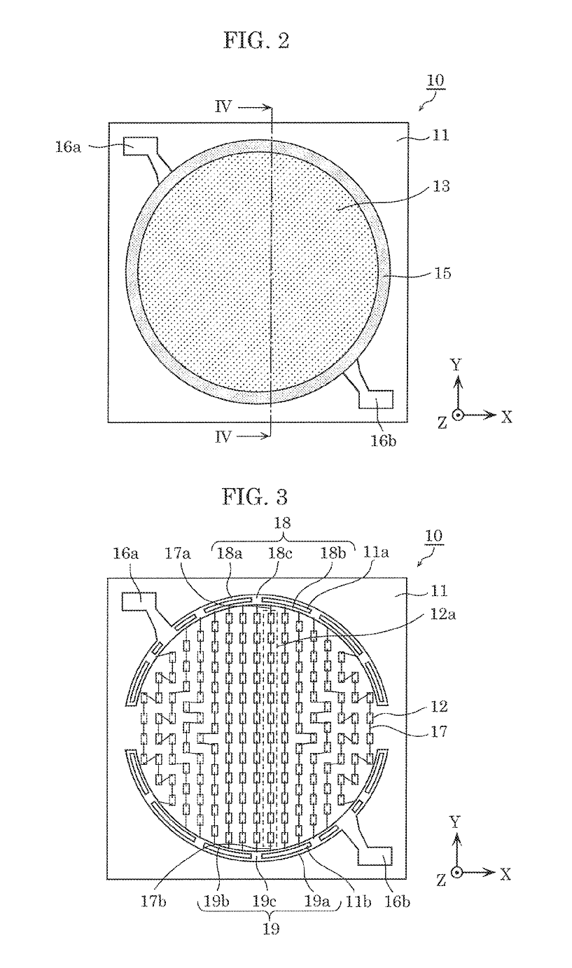

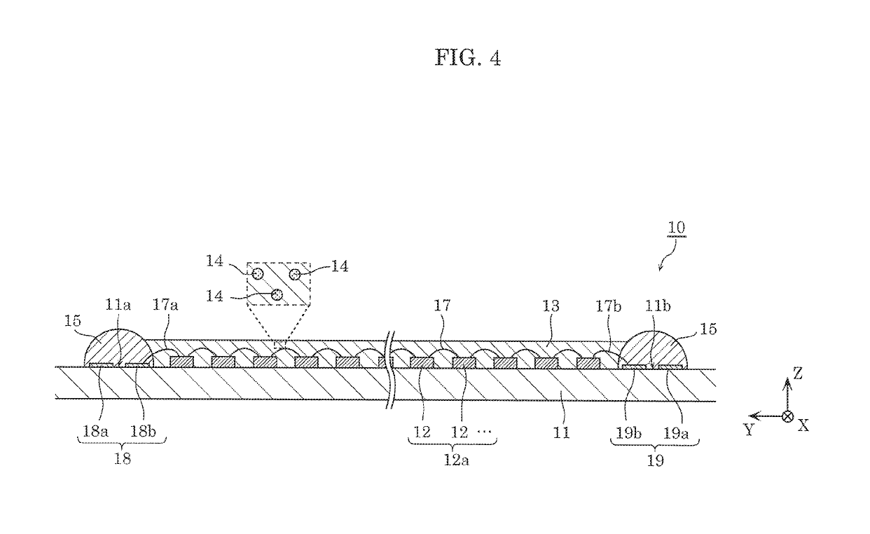

First, the configuration of a light-emitting device according to Embodiment 1 will be described with reference to the drawings. FIG. 1 is an external perspective view of the light-emitting device according to Embodiment 1. FIG. 2 is a plan view of the light-emitting device according to Embodiment 1. FIG. 3 is a plan view illustrating the internal structure of the light-emitting device according to Embodiment 1. FIG. 4 is a schematic cross-sectional view along line IV-IV in FIG. 2.

It should be noted that FIG. 3 is a plan view in which sealant 13 and enclosing component 15 are removed in FIG. 2 to show the internal structure such as the arrangement and wiring pattern of LED chips 12. In FIG. 4, illustration of the shape and grain size of green phosphor 14 is schematic and not precise.

As illustrated in FIG. 1 to FIG. 4, light-emitting device 10 according to Embodiment 1 mainly includes substrate 11, a plurality of light-emitting element rows (for example, light-emitting element row 12a) each of which includes a plurality of LED chips 12, first wire 18, second wire 19, sealant 13, enclosing component 15, first terminal 16a, second terminal 16b, and a plurality of bonding wires 17. The plurality of bonding wires 17 include bonding wire 17a, bonding wire 17b, etc.

Light-emitting device 10 is an LED module which has a chip-on-board (COB) structure in which the plurality of LED chips 12 are directly mounted on substrate 11, and emits white light. The respective structural components of light-emitting device 10 will be described below.

[Substrate]

Substrate 11 is a substrate on which the plurality of LED chips 12 are disposed. Substrate 11 is, for example, a metal-based substrate or a ceramic substrate. Furthermore, substrate 11 may be a resin substrate having resin as a base material.

As a ceramic substrate, an alumina substrate comprising aluminum oxide (alumina) or an aluminum nitride substrate comprising aluminum nitride, etc. is used. Furthermore, as a metal-based substrate, for example, an aluminum alloy substrate, a ferroalloy substrate, or a copper alloy substrate, etc., on the surface of which an insulating film is formed is used. As a resin substrate, for example, a glass-epoxy substrate comprising glass fiber and epoxy resin, etc. is used.

It should be noted that, as substrate 11, a substrate having high optical reflectance (for example, an optical reflectance of at least 90%) may be used. By using a substrate having high optical reflectance for substrate 11, the light emitted by LED chips 12 can be reflected off the surface of substrate 11. As a result, the light-extraction efficiency of light-emitting device 10 is improved. Such a substrate is exemplified by a white ceramic substrate having, for example, alumina as a base material.

Furthermore, as board 11, a light-transmissive board that is highly transmissive of light may be used. Such a substrate is exemplified by a light-transmissive ceramic substrate formed from polycrystalline alumina or aluminum nitride, a transparent glass substrate formed from glass, a crystal substrate formed from crystal, a sapphire substrate formed from sapphire, or a transparent resin substrate formed from a transparent resin material.

It should be noted that substrate 11 is quadrangular (rectangular) in a plan view, but may be another shape such as circular, etc.

[LED Chips and Light-Emitting Element Rows]

The plurality of LED chips 12 are disposed on substrate 11. LED chips 12 are an example of light-emitting elements. LED chips 12 are, for example, blue LED chips which are formed from an InGaN-based material and have a light-emission spectrum peak wavelength of at least 430 nm and at most 480 nm. Specifically, LED chips 12 emit blue light. Each of LED chips 12 on substrate 11 emits light mainly upward (positive direction in the Z-axis).

The plurality of light-emitting element rows, each of which includes a plurality of LED chips 12, are disposed on substrate 11. Each of the plurality of light-emitting element rows includes a plurality of LED chips 12 which are connected in series, chip-to-chip, by bonding wires 17. Specifically, one end of bonding wire 17 is connected to the cathode of one of two adjacent LED chips 12, and the other end of bonding wire 17 is connected to the anode of the other of the two adjacent LED chips 12. Bonding wires 17 (bonding wire 17a and bonding wire 17b) are, for example, formed from a metal material such as gold (Au), silver (Ag), or copper (Cu).

The plurality of light-emitting element rows, as a whole, form a substantially circular light emission area. In each of the plurality of light-emitting element rows, LED chip 12 located at one end is electrically connected to first wire 18 by bonding wire 17, and LED chip 12 located at the other end is electrically connected to second wire 19 by bonding wire 17.

For example, light-emitting element row 12a is configured by a plurality of LED chips 12 being disposed in a straight light along the Y-axis direction. In light-emitting element row 12a, LED chip 12 located at the end on the positive side of the Y-axis is electrically connected to first wire 18 by bonding wire 17a, and LED chip 12 located at the end on the negative side of the Y-axis direction is electrically connected to second wire 19 by bonding wire 17b. It should be noted that it is sufficient that light-emitting device 10 include at least one light-emitting element row.

[Sealant]

Next, second sealant 13 will be described. Sealant 13 collectively seals the plurality of light-emitting element rows disposed on substrate 11. As illustrated in FIG. 4, sealant 13 specifically seals the plurality of light-emitting element rows and the plurality of bonding wires 17. Sealant 13 has a function of protecting the plurality of light-emitting element rows and the plurality of bonding wires 17 from dust, moisture, outside force, etc.

Sealant 13 is formed from a light-transmissive resin material (base material) containing phosphor. The base material of sealant 13 is for example a methyl-based silicone resin, but may be an epoxy resin or a urea resin, etc.

Sealant 13, for example, contains green phosphor 14. Specifically, green phosphor 14 is, for example, an yttrium aluminum garnet (YAG)-based phosphor having a light emission peak wavelength of at least 550 nm and at most 570 nm or a Lu₃Al₅O₁₂:Ce³⁺ phosphor having a light emission peak wavelength of at least 540 nm and at most 550 nm.

There is no particular limitation on the phosphor contained in sealant 13. It is sufficient that sealant 13 contains a phosphor that emits light when excited by the light emitted by LED chips 12. Furthermore, sealant 13 may contain a filler. The filler is, for example, silica having a grain size of approximately 10 nm. By containing a filler, the filler provides resistance to prevent the phosphor from settling. Accordingly, the phosphor can be disposed in a uniformly dispersed manner inside sealant 13.

When the plurality of LED chips 12 included in the light-emitting element rows emit blue light, part of the blue light that is emitted is wavelength-converted into green light by green phosphor 14 contained in sealant 13. The blue light that is not absorbed by green phosphor 14 and the green light from the wavelength-conversion by green phosphor 14 are diffused and mixed inside sealant 13. Accordingly, white light is emitted from sealant 13. Specifically, white light is emitted from sealant 13 when the plurality of light-emitting element rows emit light.

[Terminals and Wires]

Next, terminals disposed on substrate 11 will be described. As power supply terminals for supplying power from the outside to light-emitting device 10, first terminal 16a and second terminal 16b are disposed on substrate 11. First terminal 16a and second terminal 16b are for example disposed at 2 diagonally opposed positions out of the four corners of substrate 11.

First terminal 16a and second terminal 16b are terminals for supplying power from the outside of light-emitting device 10 to the plurality of light-emitting element rows. One of first terminal 16a and second terminal 16b is a positive electrode terminal, and the other of first terminal 16a and second terminal 16b is a negative electrode terminal. When direct current power is supplied between first terminal 16a and second terminal 16b, the plurality of light-emitting element rows emit light.

Furthermore, first wire 18, which is electrically connected to first terminal 16a, is disposed on substrate 11. First wire 18 is a power supply wire for electrically connecting first terminal 16a and the plurality of light-emitting element rows. First wire 18 and first terminal 16a are electrically connected by another wire. First wire 18 and the respective light-emitting element rows are electrically connected by bonding wires 17. For example, first wire 18 and light-emitting element row 12a are electrically connected by bonding wire 17a.

First wire 18 is a ladder-shaped wire that follows a circular ring shape. Specifically, first wire 18 includes first outer wire 18a, first inner wire 18b, and a plurality of first connecting wires 18c. It should be noted that it is sufficient that first wire 18 include at least one first connecting wire 18c.

First outer wire 18a and first inner wire 18b extend in parallel along the circular ring shape. First outer wire 18a is a wire located on the outside (outer circumferential side) of the ring so as to be farther from the center of the ring than first inner wire 18b, and first inner wire 18b is located on the inside (inner circumferential side) of the ring so as to be closer to the center of the ring than first outer wire 18a. Each of first outer wire 18a and first inner wire 18b is arc-shaped (a substantially semicircular arc shape).

The width of first outer wire 18a and the width of first inner wire 18b are substantially the same, and both are less than the width in the radial direction of enclosing component 15. Furthermore, the space between first outer wire 18a and first inner wire 18b is narrower than the width in the radial direction of enclosing component 15.

Bonding wires 17 for electrically connecting first wire 18 and the light-emitting element row are connected to, for example, first inner wire 18b but may be connected to first outer wire 18a or first connecting wire 18c. In this manner, first wire 18 also functions as a bonding pad.

Each of the plurality of first connecting wires 18c is located between first outer wire 18a and first inner wire 18b, and electrically connects first outer wire 18a and first inner wire 18b. In this manner, as long as first outer wire 18a and first inner wire 18b are connected by means of the plurality of first connection wires 18c, the supply of power to the plurality of light-emitting element rows can be continued even when one of first outer wire 18a and first inner wire 18b is disconnected. Furthermore, the plurality of first connection wires 18c are disposed spaced apart in a circumferential direction. Accordingly, the distribution of current inside first wire 18 can be made close to being uniform.

It should be noted that first wire 18 only needs to be a wire that follows a ring shape, and may be a wire that follows a rectangular ring shape or a wire that follows a race track shape.

Furthermore, second wire 19, which is electrically connected to second terminal 16b, is disposed on substrate 11. Second wire 19 is a power supply wire for electrically connecting second terminal 16b and the plurality of light-emitting element rows, and is insulated from first wire 18. Second wire 19 and second terminal 16b are electrically connected by another wire. Second wire 19 and the respective light-emitting element rows are electrically connected by bonding wires 17. For example, second wire 19 and light-emitting element row 12a are electrically connected by bonding wire 17b.

Second wire 19 is a ladder-shaped wire that follows a circular ring shape. Specifically, second wire 19 includes second outer wire 19a, second inner wire 19b, and a plurality of second connecting wires 19c. It should be noted that it is sufficient that second wire 19 include at least one second connecting wire 19c.

Second outer wire 19a and second inner wire 19b extend in parallel along the circular ring shape. Second outer wire 19a is a wire located on the outside (outer circumferential side) of the ring so as to be farther from the center of the ring than second inner wire 19b, and second inner wire 19b is located on the inside (inner circumferential side) of the ring so as to be closer to the center of the ring than second outer wire 19a. Each of second outer wire 19a and second inner wire 19b is arc-shaped (a substantially semicircular arc shape).

The width of second outer wire 19a and the width of second inner wire 19b are substantially the same, and both are less than the width in the radial direction of enclosing component 15. Furthermore, the space between second outer wire 19a and second inner wire 19b is narrower than the width in the radial direction of enclosing component 15.

Bonding wires 17 for electrically connecting second wire 19 and the light-emitting element row are connected to, for example, second inner wire 19b but may be connected to second outer wire 19a or second connecting wire 19c. In this manner, first wire 19 also functions as a bonding pad.

Each of the plurality of second connecting wires 19c is located between second outer wire 19a and second inner wire 19b, and electrically connects second outer wire 19a and second inner wire 19b. In this manner, as long as second outer wire 19a and second inner wire 19b are connected by means of the plurality of second connecting wires 19c, the supply of power to the plurality of light-emitting element rows can be continued even when one of second outer wire 19a and second inner wire 19b is disconnected. Furthermore, the plurality of second connecting wires 19c are disposed spaced apart in a circumferential direction. Accordingly, the distribution of current inside second wire 19 can be made close to being uniform.

It should be noted that second wire 19 only needs to be a wire that follows a ring shape, and may be a wire that follows a rectangular ring shape or a wire that follows a race track shape.

First wire 18 and second wire 19 have a point symmetrical relationship. First wire 18 and second wire 19 may have a line symmetrical relationship. This facilitates arrangement of the plurality of light-emitting element rows in a symmetrical area.

Above-described first terminal 16a and first wire 18 are integrally formed by patterning on substrate 11. First terminal 16a and first wire 18 are, for example, formed by gold-plating processing of a metal material such as copper or silver. In this case, first terminal 16a and first wire 18 have a structure which stacks, in order of proximity to substrate 11: copper (or silver), nickel (Ni), palladium (Pd), and gold. Accordingly, corrosion, etc., of the metal material such as copper or silver can be suppressed.

In the same manner, second terminal 16b and second wire 19 are integrally formed by patterning on substrate 11. Second terminal 16b and second wire 19 are, for example, formed by gold-plating processing of a metal material such as copper or silver. In this case, second terminal 16b and second wire 19 have a structure which stacks, in order of proximity to substrate 11, copper (or silver), nickel, palladium, and gold. Accordingly, corrosion, etc., of the metal material such as copper or silver can be suppressed.

It should be noted that, in light-emitting device 10, first terminal 16a, second terminal 16b, first wire 18, and second wire 19 are not covered by an insulating film such as a cover resist.

[Enclosing Component]

Enclosing component 15 is a component that is provided on substrate 11 and functions as a dam for holding back sealant 13. Furthermore, enclosing component 15 also has a function of protecting first wire 18 and second wire 19 by covering at least part of first wire 18 and at least part of second wire 19.

As illustrated in FIG. 4, enclosing component 15 covers at least surface 11a of substrate 11 which is exposed between first outer wire 18a and first inner wire 18b, and surface 11b of substrate 11 which is exposed between second outer wire 19a and second inner wire 19b. Enclosing component 15 may also cover the entirety of first outer wire 18a and second outer wire 19a, in addition to surface 11a and surface 11b. Furthermore, enclosing component 15 may also cover the entirety of first inner wire 18b and second inner wire 19b, in addition to surface 11a and surface 11b. Furthermore, enclosing component 15 may also cover the entirety of first wire 18 and second wire 19, in addition to surface 11a and surface 11b.

For enclosing component 15, for example, a thermosetting resin or thermoplastic resin which has an insulating property is used. More specifically, silicone resin, phenol resin, epoxy resin, bismaleimide-triazine resin, or polyphthalamide (PPA), etc. is used for enclosing component 15.

In order to enhance the light-extraction efficiency of light-emitting device 10, enclosing component 15 may have a photoreflective property. In view of this, in Embodiment 1, a white resin is used for enclosing component 15. It should be noted that, in order to enhance the photoreflectivity of enclosing component 15, enclosing component 15 may contain particles of TiO₂, Al₂O₃, ZrO₂, MgO, etc.

In a plan view, enclosing component 15 is of a circular ring shape surrounding the plurality of light-emitting element rows and sealant 13 from the side. The majority of first wire 18 and second wire 19 are located under enclosing component 15. It should be noted that enclosing component 15 only needs to be ring shaped, and may be of a rectangular ring shape or a race track shape.

[Advantageous Effects of First Wire and Second Wire]

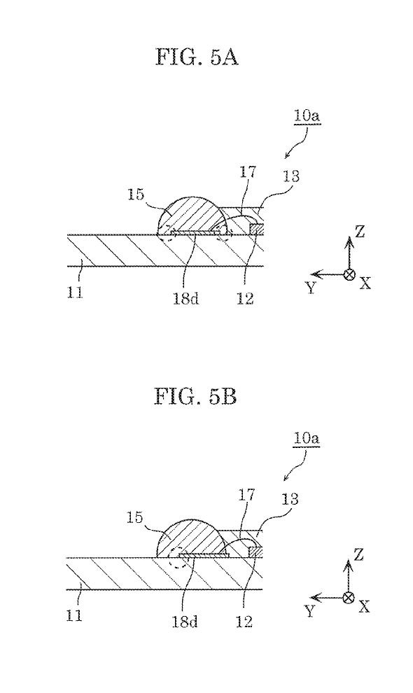

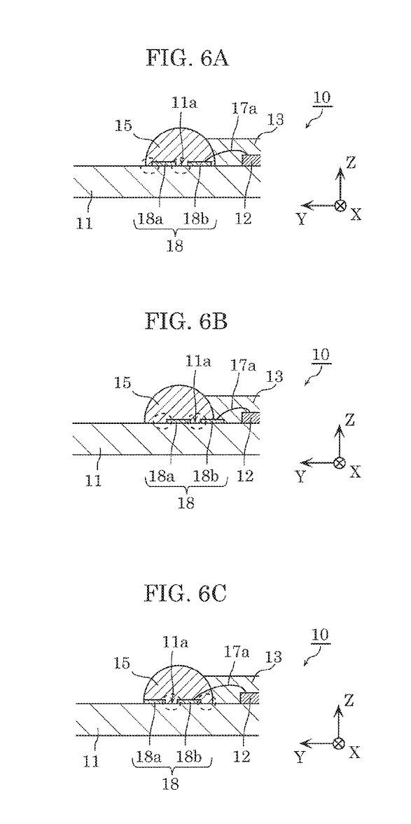

As described above, in a plan view, first wire 18 and second wire 19 are ladder-shaped and covered by enclosing component 15. The advantageous effects that can be obtained with such a configuration will be described with reference to a comparative example. FIG. 5A and FIG. 5B are schematic cross-sectional view of configurations of a light-emitting device according to a comparative example. FIG. 6A to FIG. 6C are schematic cross-sectional views in which the periphery of first wire 18 of light-emitting device 10 is illustrated magnified.

As illustrated in FIG. 5A and FIG. 5B, in light-emitting device 10a according to the comparative example, wire 18d having a typical linear shape instead of a ladder shape is covered by enclosing component 15. In light-emitting device 10a, preventing detachment of enclosing component 15 poses a challenge. Since the connection between enclosing component 15 and wire 18d (gold-plated layer) is weaker than the connection between enclosing component 15 and the surface of substrate 11, it is possible to prevent the detachment of enclosing component 15 by increasing the contact locations (contact area) between enclosing component 15 and the surface of substrate 11.

Here, when the contact area between enclosing component 15 and substrate 11 is increased by increasing the width of enclosing component 15 so as to prevent the detachment of enclosing component 15, there is the concern that substrate 11 will become big. Furthermore, it is also possible to prevent the detachment of enclosing component 15 by increasing the contact area between enclosing component 15 and substrate 11 by reducing the width of wire 18d (making wire 18d into a narrow wire). In this case, increase of resistance of wire 18d and disconnection due to heat or corrosion of wire 18d become a concern.

In contrast, in light-emitting device 10, contact between enclosing component 15 and surface 11a of substrate 11, which is exposed between first outer wire 18a and first inner wire 18b, can reduce such concerns and prevent detachment of enclosing component 15.

Furthermore, in light-emitting device 10, detachment of enclosing component 15 can be prevented even when enclosing component 15 is displaced.

As illustrated in FIG. 5A, when enclosing component 15 is disposed to cover both ends in the Y-axis direction of wire 18d in light-emitting device 10a, enclosing component 15 contacts the surface of substrate 11 at two locations (the two locations indicated by broken line circles in FIG. 5A). In contrast, as illustrated in FIG. 5B, when enclosing component 15 is displaced, enclosing component 15 contacts the surface of substrate 11 at one location, and thus detachment of enclosing component 15 is more likely to occur. In this manner, in light-emitting device 10a according to the comparative example, detachment of enclosing component 15 tends to occur when enclosing component 15 is displaced.

In contrast, in light-emitting device 10, first wire 18 is ladder-shaped, and, as illustrated in FIG. 6A, surface 11a of substrate 11 is exposed between first outer wire 18a and first inner wire 18b. When enclosing component 15 is disposed so as to cover both ends in the Y-axis direction of first wire 18, enclosing component 15 contacts the surface of substrate 11 at three locations. Furthermore, even when enclosing component 15 is displaced to the positive side of the Y-axis as illustrated in FIG. 6B or even when enclosing component 15 is displaced to the negative side of the Y-axis as illustrated in FIG. 6C, enclosing component 15 contacts the surface of substrate 11 in at least two locations. Therefore, in light-emitting device 10, detachment of enclosing component 15 can be prevented even when enclosing component 15 is displaced. It should be noted that, although not specifically illustrated in the figures, second wire 19 also produces the advantageous effect of preventing detachment of enclosing component 15 in the same manner as first wire 18.

[Variation 1]

A plurality of light-emitting element rows (a plurality of LED chips 12) and alignment marks (recognition marks) which serve as markers for mounting the plurality of bonding wires 17 are disposed on substrate 11. The alignment marks are integrally formed by patterning on substrate 11 together with, for example, first terminal 16a, second terminal 16b, first wire 18, and second wire 19. Specifically, the alignment marks are, for example, metal films.

At this time, when the alignment marks are disposed inward of first wire 18 and second wire 19 (inward of enclosing component 15), there is a possibility that light emitted by the light-emitting element rows will be absorbed and thus light emission efficiency will deteriorate. Furthermore, there are cases where the arrangement space of the plurality of light-emitting element rows becomes narrow.

On the other hand, when the alignment marks are disposed outward of first wire 18 and second wire 19 (outward of enclosing component 15), the alignment marks make creepage distance short, and there are cases where it is necessary to enlarge substrate 11 in order to ensure creepage distance. Furthermore, there is also concern that the outside appearance (good outward appearance) will be ruined by the alignment marks.

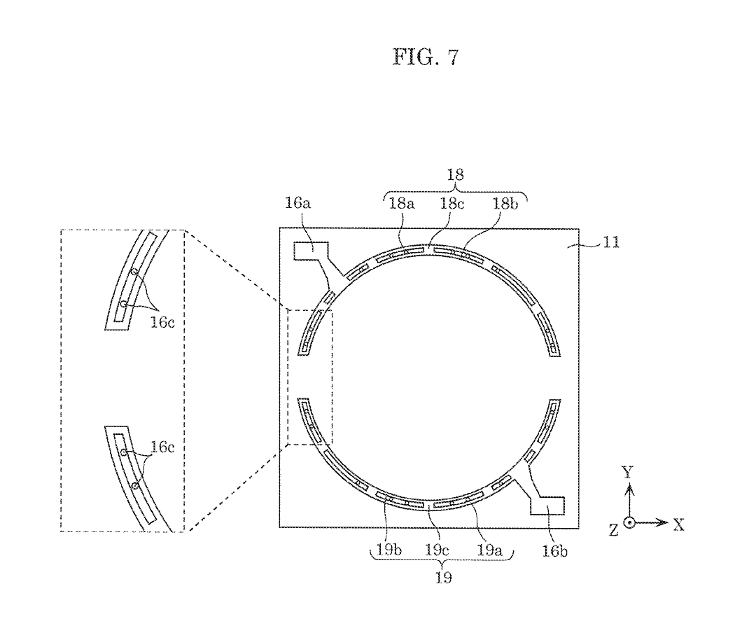

In view of this, the alignment marks may be disposed on substrate 11 between first outer wire 18a and first inner wire 18b or may be disposed on substrate 11 between second outer wire 19a and second inner wire 19b. FIG. 7 is a plan view illustrating alignment marks disposed on substrate 11.

In the example in FIG. 7, alignment marks 16c are dot-shaped (circle-shaped) metal films, and are insulated from first wire 18 and second wire 19. A plurality of alignment marks 16c are disposed on the surface of substrate 11 which is exposed between first outer wire 18a and first inner wire 18b and on the surface of substrate 11 which is exposed between second outer wire 19a and second inner wire 19b.

In this manner, alignment marks 16c may be disposed using the space on substrate 11 between first outer wire 18a and first inner wire 18b and the space on substrate 11 between second outer wire 19a and second inner wire 19b. Accordingly, the above-described deterioration of light emission efficiency, narrowing of the arrangement space of the plurality of light-emitting element rows, enlargement of substrate 11, and ruining of the outside appearance can be prevented.

It should be noted that alignment marks 16c may be of a shape other than a dot, as long as it is a shape that enables equipment (e.g., a camera) for manufacturing light-emitting device 10 to recognize alignment marks 16c. Furthermore, above-described first connecting wire 18c or second connecting wire 19c may be used as an alignment mark.

[Variation 2]

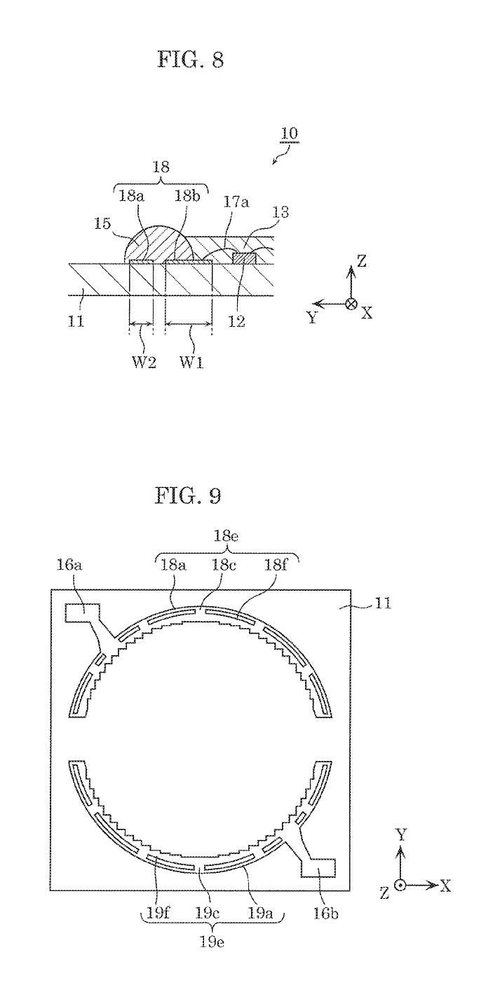

Although bonding wire 17a electrically connecting first wire 18 and light-emitting element row 12a is disposed straddling sealant 13 and enclosing component 15 in the examples illustrated in FIG. 4, FIG. 6A, and FIG. 6C, the entirety of bonding wire 17a may be sealed by sealant 13. FIG. 8 is a schematic cross-sectional view of the light-emitting device in which the entirety of bonding wire 17a is sealed by sealant 13.

In the example in FIG. 8, bonding wire 17a is connected to first inner wire 18b out of first wire 18, and the entirety of bonding wire 17a is sealed by sealant 13. When bonding wire 17a is disposed straddling sealant 13 and enclosing component 15, there is a possibility that bonding wire 17a will be damaged or deformed in a reliability test due to the difference between the thermal expansion coefficients of sealant 13 and enclosing component 15. In contrast, if the entirety of bonding wire 17a is sealed by sealant 13 alone, damaging or deformation of bonding wire 17a due to the reliability test is prevented.

Furthermore, width W1 of first inner wire 18b is greater than width W2 of first outer wire 18a. This facilitates part of first inner wire 18b inward of enclosing component 15, and facilitates sealing the entirety of bonding wire 17a using sealant 13.

It should be noted that, when width W1 of first inner wire 18b is greater than width W2 of first outer wire 18a, bonding of bonding wire 17a to first inner wire 18b becomes comparatively easy. Such an advantageous effect can be obtained even with a configuration in which bonding wire 17a is disposed straddling sealant 13 and enclosing component 15. Therefore, in a configuration in which bonding wire 17a is disposed straddling sealant 13 and enclosing component 15, width W1 of first inner wire 18b may be greater than width W2 of first outer wire 18a.

It should be noted that, although not illustrated in the figures, the entirety of bonding wire 17b may be sealed by sealant 13, and the width of second inner wire 19b may be greater than the width of second outer wire 19a.

[Variation 3]

In a plan view, the inner side of first inner wire 18b may include a plurality of projections which function as pads for the bonding of bonding wire 17a. Accordingly, bonding of bonding wire 17a to first inner wire 18b becomes comparatively easy. The same is true for second inner wire 19b.

Furthermore, in a plan view, at least part of the inner side of first inner wire 18b and at least part of the inner side of second inner wire 19b may be step-shaped. FIG. 9 is a plan view of a first inner wire and a second inner wire which have inner sides that are step-shaped.

First wire 18e illustrated in FIG. 9 includes first outer wire 18a, first inner wire 18f, and a plurality of first connecting wires 18c. The inner edge of first inner wire 18f is step-shaped, and includes a plurality of corner portions which form 90-degree angles.

Such step-shaped portions in the inner side of first inner wide 18f not only function as pads for the bonding of bonding wire 17a, but can also be used as alignment marks. Since the corner portions which form 90-degree angles, in particular, are easily recognizable by manufacturing equipment (camera), the mounting precision of the plurality of light-emitting element rows (the plurality of LED chips 12) and the plurality of bonding wires 17 can be improved.

In the same manner, second wire 19e includes second outer wire 19a, second inner wire 19f, and a plurality of second connecting wires 19c. The inner edge of second inner wire 19f is step-shaped, and includes a plurality of corner portions which form 90-degree angles.

Such step-shaped portions in the inner side of second inner wire 19f not only function as pads for the bonding of bonding wire 17b, but can also be used as alignment marks. Since the corner portions which form 90-degree angles, in particular, are easily recognizable by manufacturing equipment (camera), the mounting precision of the plurality of light-emitting element rows (the plurality of LED chips 12) and the plurality of bonding wires 17 can be improved.

[Advantageous Effects, Etc.]

As described above, light-emitting device 10 includes: substrate 11, light-emitting element row 12a disposed on substrate 11; first wire 18 disposed on substrate 11; bonding wire 17a electrically connecting light-emitting element row 12a and first wire 18; sealant 13 that seals light-emitting element row 12a; and enclosing component 15 that is in a shape of a ring and surrounds sealant 13. Bonding wire 17a is an example of a first bonding wire.

First wire 18 includes: first outer wire 18a and first inner wire that run in parallel along the ring, with first inner wire 18b being located inward of first outer wire 18a; and first connecting wire 18c located between first outer wire 18a and first inner wire 18b and electrically connecting first outer wire 18a and first inner wire 18b. Enclosing component 15 covers surface 11a of substrate 11 exposed between first outer wire 18a and first inner wire 18b.

Accordingly, in a configuration in which first wire 18 is covered by enclosing component 15, detachment of enclosing component 15 can be prevented.

Furthermore, enclosing component 15 may further cover first outer wire 18a.

Accordingly, in a configuration in which first outer wire 18a is covered by enclosing component 15, detachment of enclosing component 15 can be prevented.

Furthermore, enclosing component 15 may further cover first inner wire 18b.

Accordingly, in a configuration in which first inner wire 18b is covered by enclosing component 15, detachment of enclosing component 15 can be prevented.

Furthermore, enclosing component 15 may further cover first wire 18.

Accordingly, in a configuration in which first wire 18 is covered by enclosing component 15, detachment of enclosing component 15 can be prevented.

Furthermore, width W1 of first inner wire 18b may be greater than width W2 of first outer wire 18a, and bonding wire 17a may be electrically connected to first inner wire 18b.

This facilitates bonding of bonding wire 17a to first inner wire 18b.

Furthermore, in the same manner as first inner wire 18f, in a plan view, at least part of the inner side of first inner wire 18b may be step-shaped.

Accordingly, the step-shaped portion in the inner side of first inner wire 18b can be used as pads for the bonding of bonding wire 17b and as alignment marks.

Furthermore, light-emitting device 10 may further include alignment mark 16c that is disposed on substrate 11 between first outer wire 18a and first inner wire 18b, and insulated from first wire 18. Alignment mark 16c is an example of a metal film.

Accordingly, it is possible to dispose alignment marks 16c using the space on substrate 11 between first outer wire 18a and first inner wire 18b.

Furthermore, alignment mark 16c may be a dot.

Accordingly, the recognition accuracy of manufacturing equipment (camera) for alignment marks 16c can be enhanced. In other words, the mounting precision for light-emitting element row 12a and the plurality of bonding wires 17 can be improved.

Furthermore, sealant 13 may further seal the entirety of bonding wire 17a.

Accordingly, it is possible to prevent bonding wire 17a from becoming damaged or deformed in a reliability test under extreme conditions.

Furthermore, light-emitting device 10 may further include first terminal 16a for supplying power from the outside of light-emitting device 10 to light-emitting element row 12a. First terminal 16a is disposed outward of enclosing component 15 on substrate 11, and is electrically connected to first wire 18.

This facilitates supply of power from the outside to light-emitting device 10.

Furthermore, light-emitting device 10 may further include second wire 19 disposed on substrate 11 and insulated from first wire 18, and bonding wire 17b electrically connecting light-emitting element row 12a and second wire 19. Bonding wire 17b is an example of a second bonding wire. Second wire 19 may include: second outer wire 19a and second inner wire 19b that run in parallel along the ring, with second inner wire 19b being located inward of second outer wire 19a; and second connecting wire 19c located between second outer wire 19a and second inner wire 19b and electrically connecting second outer wire 19a and second inner wire 19b. Enclosing component 15 may further cover surface 11b of substrate 11 exposed between second outer wire 19a and second inner wire 19b.

Accordingly, in a configuration in which second wire 19 is covered by enclosing component 15, detachment of enclosing component 15 can be prevented.

Furthermore, first wire 18 and second wire 19 may have a line symmetrical relationship.

This facilitates arrangement of the plurality of light-emitting element rows in a symmetrical area.

Furthermore, the present invention may be realized as a mounting board (a substrate before light-emitting element row 12a, sealant 13, enclosing component 15, etc., are mounted (placed), and on which first wire 18, second wire 19, first terminal 16a, second terminal 16b, etc., are formed). Such a mounting board is a mounting board on which light-emitting element row 12a and enclosing component 15 that is in a shape of a ring and surrounds light-emitting element row 12a are to be mounted. The mounting board includes substrate 11 and first wire 18 disposed on substrate 11, and first wire 18 includes: first outer wire 18a and first inner wire 18b that run in parallel along the ring, with first inner wire 18b being located inward of first outer wire 18a; and first connecting wire 18c located between first outer wire 18a and first inner wire 18b and electrically connecting first outer wire 18a and first inner wire 18b.

Accordingly, in a configuration in which first wire 18 is covered by enclosing component 15, detachment of enclosing component 15 can be prevented.

### Embodiment 2

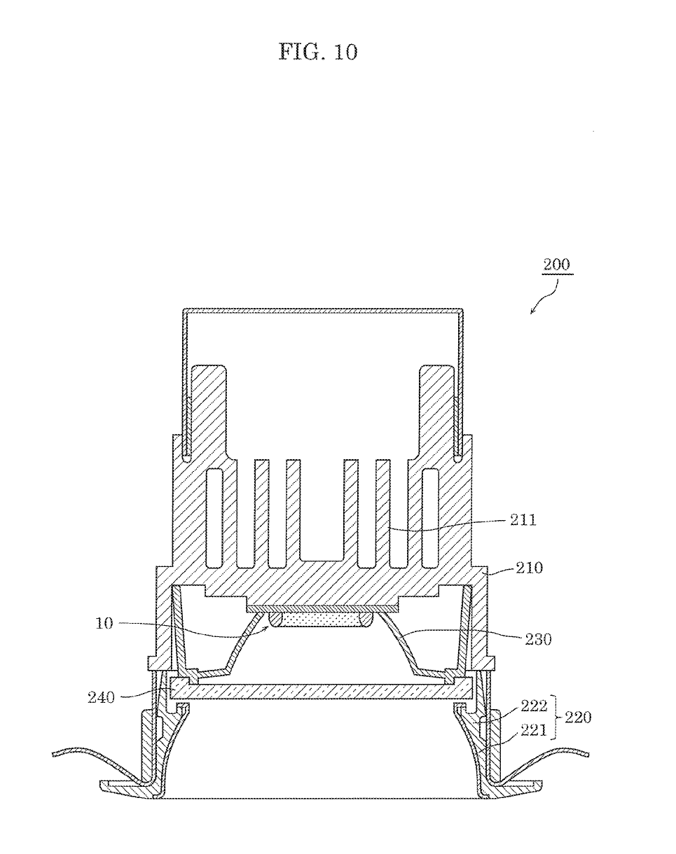

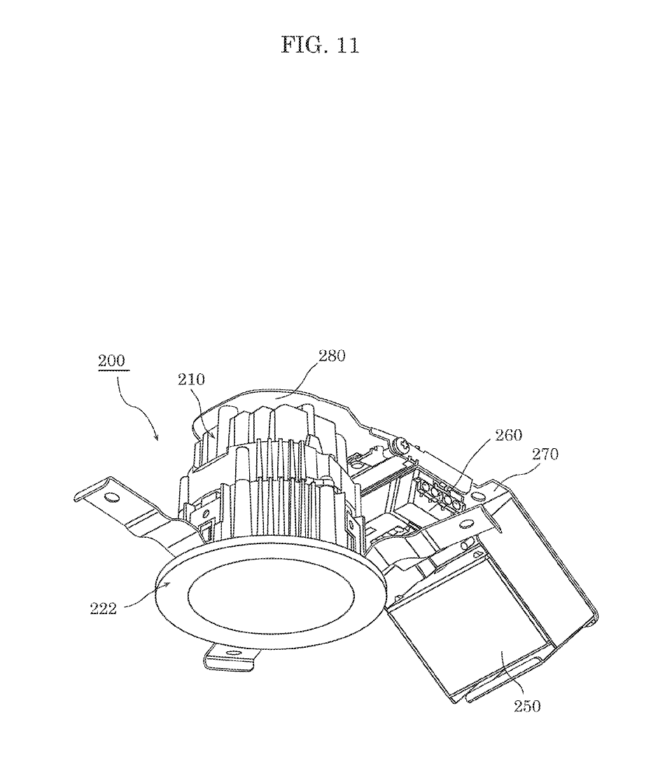

Next, an illuminating apparatus according to Embodiment 2 will be described using FIG. 10 and FIG. 11. FIG. 10 is a cross-sectional view of the illuminating apparatus according to Embodiment 2. FIG. 11 is an external perspective view of the illuminating apparatus and peripheral components thereof according to Embodiment 2.

As illustrated in FIG. 10 and FIG. 11, illuminating apparatus 200 according to Embodiment 2 is, for example, a recessed illuminating apparatus such as a downlight that is set by being recessed into the ceiling of a house, so as to emit light to a space below it (i.e., a corridor, a wall, etc.).

Illuminating apparatus 200 includes light-emitting device 10. Illuminating apparatus 200 further includes: a substantially cylindrical, bottomed apparatus body formed by joining base 210 and frame 220; and reflector 230 and light-transmissive panel 240 which are disposed in the apparatus body.

Base 210 is an attachment base to which light-emitting device 10 is attached, and is a heat sink that dissipates the heat generated by light-emitting device 10. Base 210 is formed in a substantially columnar shape using a metal material, and comprises die-cast aluminum in Embodiment 2.

A plurality of heat-dissipating fins 211 projecting upward are provided on the top portion (ceiling-side portion) of base 210, at regular intervals along one direction. With this, the heat generated by light-emitting device 10 can be efficiently dissipated.

Frame 220 includes cone 221 which is substantially cylindrical and has a reflecting face in an inner surface, and frame body 222 to which cone 221 is attached. Cone 221 is formed from a metal material, and can be fabricated, for example, by drawing or press-forming an aluminum alloy, etc. Frame body 222 is formed from a rigid resin material or a metal material. Frame 220 is fixed by attaching frame body 222 to base 210.

Reflector 230 is an annular frame-shaped (funnel-shaped) reflecting component having an internal reflection function. Reflector 230 can be formed from a metal material such as aluminum. It should be noted that reflector 230 may be formed from a rigid white resin material instead of a metal material.

Light-transmissive panel 240 is a light-transmissive component having a light-diffusing property and a light-transmissive property. Light-transmissive panel 240 is a flat plate disposed between reflector 230 and frame 220, and is attached to reflector 230. Light-transmissive panel 240 can be formed in the shape of a disc using a transparent resin material such as acrylic, polycarbonate, etc.

It should be noted that illuminating apparatus 200 need not include light-transmissive panel 240. By not including light-transmissive panel 240, the luminous flux of the light emitted from illuminating apparatus 200 can be improved.

Furthermore, as illustrated in FIG. 11, in illuminating apparatus 200, lighting device 250 and terminal base 260 are connected to light-emitting device 10. Lighting device 250 supplies power for causing light-emitting device 10 to light up, and terminal base 260 relays alternating current power from a commercial power supply to lighting device 250. Specifically, lighting device 250 converts the alternating current power relayed from terminal base 260 into direct current power, and outputs the direct current power to light-emitting device 10.

Lighting device 250 and terminal base 260 are fixed to attaching board 270 which is provided separately from the apparatus body. Attaching board 270 is formed by bending a rectangular board-like component comprising a metal material. Lighting device 250 is fixed to the bottom surface of one end portion in the lengthwise direction of attaching board 270, and terminal base 260 is fixed to the bottom surface of the other end portion in the lengthwise direction of attaching board 270. Attaching board 270 and top board 280, which is fixed to the top portion of base 210 of the apparatus body, are linked to each other.

As described above, illuminating apparatus 200 includes light-emitting device 10 and lighting device 250 which supplies light-emitting device 10 with power for causing light-emitting device 10 to light-up. Accordingly, in illuminating apparatus 200, detachment of enclosing component 15 can be prevented.

It should be noted that although a downlight is given as an example of an illuminating apparatus in Embodiment 2, the present invention may be realized as another illuminating apparatus such as a spotlight, etc.

### OTHER EMBODIMENTS

Although a light-emitting device and an illuminating apparatus according to exemplary embodiments have been described thus far, the present invention is not limited to the foregoing exemplary embodiments.

Although, in the foregoing exemplary embodiments, the light-emitting device discharges white light through a combination of LED chips emitting blue light and a green phosphor, the configuration for discharging white light is not limited to such. For example, LED chips emitting blue light and a green phosphor and a red phosphor may be combined. Specifically, the sealant may contain a green phosphor and a red phosphor. Furthermore, a yellow phosphor may be combined in place of the green phosphor or in addition to the green phosphor. Alternatively, ultraviolet light-emitting ultraviolet LED chips which have a shorter wavelength than blue light-emitting LED chips and a blue phosphor, a green phosphor, and a red phosphor which emit blue light, green light, and red light when excited by mainly ultraviolet light may be combined. Specifically, the LED chips may emit ultraviolet light, and the sealant may contain a blue phosphor, a green phosphor, and a red phosphor.

Furthermore, the light-emitting device may emit light of a color other than white. For example, when the light-emitting device emits blue light, the sealant need not contain phosphor.

Furthermore, in the foregoing exemplary embodiments, an LED chip mounted on the substrate is connected, chip-to-chip, with another LED chip by a bonding wire. However, an LED chip may be connected by a bonding wire to wiring (metal film) provided on the board, and electrically connected to another LED chip via the wiring.

Furthermore, in the foregoing exemplary embodiments, an LED chip is given as an example of a light-emitting element used in the light-emitting device. However, a semiconductor light-emitting element such as a semiconductor laser or a solid-state light-emitting element such as an organic electroluminescent (EL) element or an inorganic EL element may be employed as a light-emitting element.

Furthermore, two or more types of light-emitting elements that emit light of different colors may be used in the light-emitting device. For example, in addition to LED chips that emit blue light, the light-emitting device may also include LED chips that emit red light for the purpose of enhancing color rendering property.

Forms obtained by various modifications to the respective exemplary embodiments that can be conceived by a person of skill in the art as well as forms realized by arbitrarily combining structural components and functions in the respective exemplary embodiments that are within the scope of the essence of the present invention are included in the present invention. For example, the present invention may be realized as a method of manufacturing the light-emitting device described in the foregoing exemplary embodiments.

What is claimed is:

1. A light-emitting device, comprising:
a substrate;
a light-emitting element row disposed on the substrate;
a first wire disposed on the substrate;
a first bonding wire electrically connecting the light-emitting element row and the first wire;
a sealant that seals the light-emitting element row; and
an enclosing component that is in a shape of a ring and surrounds the sealant, wherein
the first wire includes:
a first outer wire and a first inner wire that run in parallel along the ring, the first inner wire being located inward of the first outer wire; and
a first connecting wire that is located between the first outer wire and the first inner wire, and electrically connects the first outer wire and the first inner wire, and
the enclosing component covers a surface of the substrate exposed between the first outer wire and the first inner wire.

2. The light-emitting device according to claim 1, wherein
the enclosing component further covers the first outer wire.

3. The light-emitting device according to claim 1, wherein
the enclosing component further covers the first inner wire.

4. The light-emitting device according to claim 1, wherein
the enclosing component further covers the first wire.

5. The light-emitting device according to claim 1, wherein
the first inner wire has a width greater than a width of the first outer wire, and
the first bonding wire is electrically connected to the first inner wire.

6. The light-emitting device according to claim 1, wherein
in a plan view, at least part of an inner side of the first inner wire is step-shaped.

7. The light-emitting device according to claim 1, further comprising:
a metal film that is disposed on the substrate between the first outer wire and the first inner wire, and insulated from the first wire.

8. The light-emitting device according to claim 7, wherein
the metal film is in a shape of a dot.

9. The light-emitting device according to claim 7, comprising:
a plurality of metal films each of which is the metal film.

10. The light-emitting device according to claim 1, wherein
the sealant further seals an entirety of the first bonding wire.

11. The light-emitting device according to claim 1, further comprising:
a first terminal for supplying power from outside of the light-emitting device to the light-emitting element row, wherein
the first terminal is disposed outward of the enclosing component on the substrate, and is electrically connected to the first wire.

12. The light-emitting device according to claim 1, further comprising:
a second wire disposed on the substrate and insulated from the first wire; and
a second bonding wire electrically connecting the light-emitting element row and the second wire, wherein
the second wire includes:
a second outer wire and a second inner wire that run in parallel along the ring, the second inner wire being located inward of the second outer wire; and
a second connecting wire that is located between the second outer wire and the second inner wire, and electrically connects the second outer wire and the second inner wire, and
the enclosing component further covers a surface of the substrate exposed between the second outer wire and the second inner wire.

13. The light-emitting device according to claim 12, wherein
the first wire and the second wire have one of a point symmetrical relationship and a line symmetrical relationship.

14. The light-emitting device according to claim 1, wherein
the enclosing component is in a shape of a circular ring, and
the first outer wire and the first inner wire run in parallel along the circular ring.

15. The light-emitting device according to claim 1, wherein
the first wire includes a plurality of first connecting wires each of which is the first connecting wire.

16. An illuminating apparatus, comprising:
the light-emitting device according to claim 1; and
a lighting device that supplies, to the light-emitting device, power for causing the light-emitting device to emit light.

17. A mounting board on which a light-emitting element row and an enclosing component that is in a shape of a ring and surrounds the light-emitting element row are to be disposed, the mounting board comprising:
a substrate; and
a first wire disposed on the substrate, wherein
the first wire includes:
a first outer wire and a first inner wire that run in parallel along the ring, the first inner wire being located inward of the first outer wire; and
a first connecting wire that is located between the first outer wire and the first inner wire, and electrically connects the first outer wire and the first inner wire.
